(19) United States
(12) Patent Application Publication
(10) Pub. No.: US 2019/0215988 A1
(43) Pub. Date: Jul. 11, 2019

(54) VAPOR CHAMBER AND HEAT DISSIPATION DEVICE

(71) Applicant: GETAC TECHNOLOGY CORPORATION, Hsinchu County (TW)

(72) Inventor: Chi-Jung WU, Taipei City (TW)

(21) Appl. No.: 16/030,827

(22) Filed: Jul. 9, 2018

(30) Foreign Application Priority Data
Jan. 5, 2018 (CN) 201810010230.4

(51) Int. Cl. H05K 7/20

(52) U.S. Cl. CPC H05K 7/20336; H05K 7/20318; H05K 7/20309; H05K 7/20327

(57) ABSTRACT

A vapor chamber is provided and includes channels, working fluids and a first buffer zone. The working fluids undergo evaporation and condensation alternately in the channels, respectively. The first buffer zone is defined between every two adjacent channels to enable mechanical processing. The first buffer zone divides the channels into a first heat dissipation portion and a second heat dissipation portion. Owing to the first heat dissipation portion and the second heat dissipation portion, the vapor chamber copes well with different heat sources to effectuate heat dissipation.

### CROSS-REFERENCE TO RELATED APPLICATIONS

This application claims priority from China Patent Application No. 201810010230.4, filed on Jan. 5, 2018, the entire disclosure of which is hereby incorporated by reference.

### BACKGROUND OF THE INVENTION

### Field of the Invention

The present invention relates to vapor chambers and heat dissipation devices and, more particularly, to a vapor chamber capable of transferring heat in circulation by working fluids and a heat dissipation device.

### Description of the Prior Art

Being increasingly versatile, electronic devices have more and more heat sources generating heat while the electronic devices are operating. To remove heat source-generated heat from the electronic devices, the electronic devices are each equipped with a vapor chamber to enhance heat dissipation.

A conventional vapor chamber is usually panel-shaped and has therein some closed cavities for receiving working fluids. Heat inside the vapor chamber comes into contact with the working fluids, and thus the working fluids evaporate continuously, thereby allowing the heat to be dissipated continuously. To retain its closed cavity structure, the packaged vapor chamber must not be mechanically processed, for example, bent, again; as a result, the vapor chamber cannot extend to different planes. Furthermore, electronic devices each comprise a wide variety of parts and components, and the parts and components are of different shapes; as a result, the panel-shaped vapor chamber mounted in an electronic device is likely to spatially interfere with various parts and components in the electronic device, thereby causing drawbacks described below. The electronic device has limited internal space for receiving the vapor chamber. The vapor chamber cannot correspond in position to every heat source inside the electronic device. Vapor chambers disposed between different heat sources in the electronic device are self-contained, and thus the vapor chambers cannot be coordinated in dissipating heat; as a result, heat cannot be completely removed from the electronic device, and in consequence the performance of the electronic device deteriorates.

### SUMMARY OF THE INVENTION

The present invention provides a vapor chamber which comprises a plurality of channels, a plurality of working fluids and a first buffer zone. The working fluids undergo evaporation and condensation alternately in the channels, respectively. A first buffer zone is defined between every two adjacent channels to enable mechanical processing. The first buffer zone divides the channels into a first heat dissipation portion and a second heat dissipation portion. Therefore, one single vapor chamber copes well with heat sources located at different positions such that heat generated from the heat sources is completely removed.

The present invention further provides a heat dissipation device adapted to dissipate heat generated from heat sources. The heat dissipation device comprises a casing and a vapor chamber. The vapor chamber is received in the casing. The vapor chamber has a top side and a bottom side opposing the top side. The heat sources are disposed at the vapor chamber. The vapor chamber comprises a plurality of channels, a plurality of working fluids and a first buffer zone. The channels each extend from the bottom side to the top side. The working fluids undergo evaporation and condensation alternately in the channels, respectively. The first buffer zone is defined between every two adjacent ones of the channels to enable mechanical processing. The first buffer zone divides the channels into a first heat dissipation portion and a second heat dissipation portion.

Therefore, the first heat dissipation portion and the second heat dissipation portion of the vapor chamber dissipate heat generated from different heat sources to enhance heat dissipation.

### BRIEF DESCRIPTION OF THE DRAWINGS

FIG. 1 is a schematic view of a vapor chamber according to an embodiment of the present invention;

FIG. 2 is a cutaway view of the vapor chamber according to the aforesaid embodiment of the present invention;

FIG. 3 is a partial enlarged view of an encircled part 3 in FIG. 2;

FIG. 4 is a schematic view of the vapor chamber according to another embodiment of the present invention;

FIG. 5 is a schematic view of the vapor chamber according to yet another embodiment of the present invention;

FIG. 6 is a schematic view of the vapor chamber according to still yet another embodiment of the present invention;

FIG. 7 is a schematic view of the vapor chamber according to a further embodiment of the present invention;

FIG. 8 is an exploded perspective view of a heat dissipation device comprising the vapor chamber according to an embodiment of the present invention;

FIG. 9 is an assembled perspective view of the embodiment in FIG. 8;

FIG. 10 is a partial cross-sectional view of FIG. 9; and

FIG. 11 is a partial enlarged view of an encircled part 11 in FIG. 10.

### DETAILED DESCRIPTION OF THE EMBODIMENTS

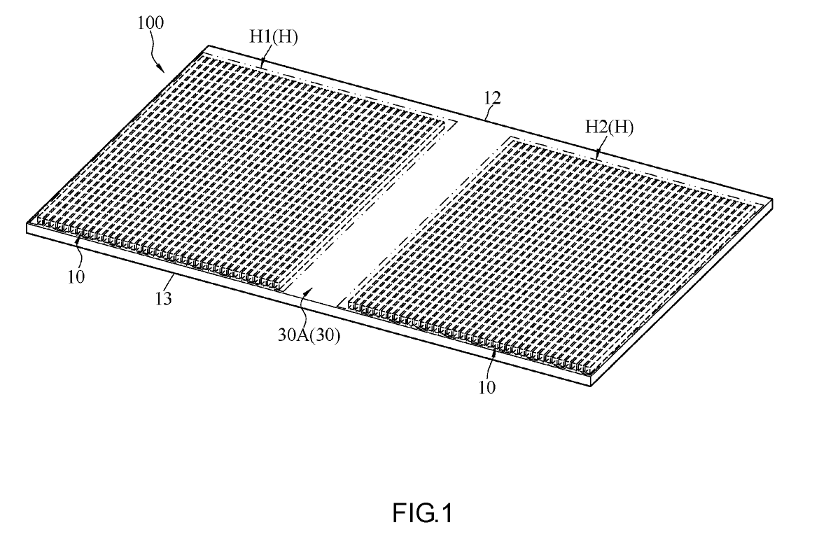

Referring to FIG. 1 through FIG. 3, there are shown schematic views of a vapor chamber 100 according to an embodiment of the present invention. As shown in FIG. 1 through FIG. 3, the vapor chamber 100 comprises a plurality of channels 10, a plurality of working fluids 20 and a buffer zone 30. The working fluids 20 are received in the channels 10, respectively, to undergo evaporation and condensation alternately. The buffer zone 30 is defined between every two adjacent channels 10 to enable mechanical processing. The buffer zone 30 divides the channels 10 into different heat dissipation portions H. The heat dissipation portions H each have at least one channel 10. Owing to the buffer zone 30 and the heat dissipation portions H, the vapor chamber 100 works well with different heat source positions or meets different mounting requirements and thus is more effective in dissipating heat.

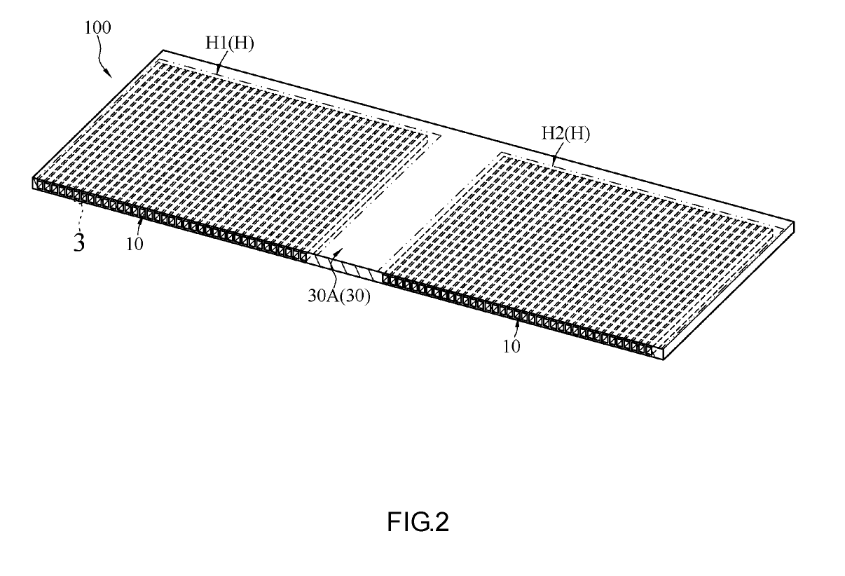

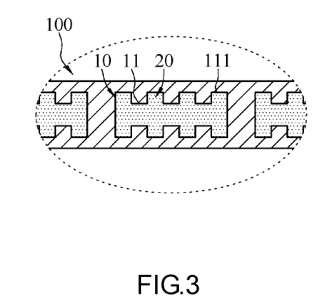

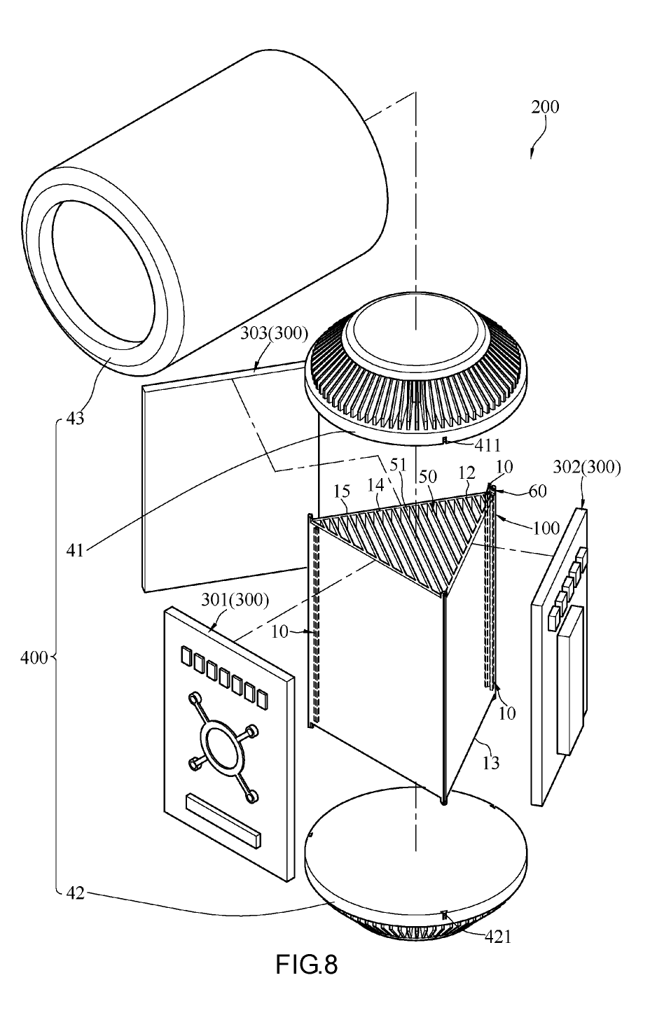

Referring to FIG. 1, FIG. 2, FIG. 3 and FIG. 8, the vapor chamber 100 functions as a heat dissipation device 200 to dissipate heat generated from heat sources 300 of the heat dissipation device 200. As shown in FIG. 8, the heat sources 300 are motherboards (i.e., printed circuit boards which electronic components are mounted on) or the electronic components. When heat is generated from the heat sources 300 because of operation thereof, the heat is transferred to the vapor chamber 100. Then, the heat comes into contact with the working fluids 20 in the vapor chamber 100, and thus the working fluids 20 evaporate into vapor. The vapor flows within the channels 10. The aforesaid evaporation is endothermic and is accompanied by the formation of an evaporation zone. Liquid within the evaporation zone evaporates into gas. As soon as the vapor reaches any cooler point in the channels 10, the vapor condenses and turns into liquid. The aforesaid condensation is exothermic and is accompanied by the formation of a condensation zone. Upon its entry into the condensation zone, the vapor condenses into liquid. Afterward, the liquid comes into contact with heat and thus evaporates again. Therefore, the working fluids 20 in the channels 10 alternate between endothermic evaporation and exothermic condensation continually and thus alternate between the evaporation zone and the condensation zone continually such that the heat inside the vapor chamber 100 spreads quickly to therefore dissipate heat from the heat sources 300.

In an embodiment, the vapor chamber 100 is a panel-shaped structure made of a metal with excellent heat transfer capability, such as aluminum or copper, but the present invention is not limited thereto. The vapor chamber 100 has therein the channels 10. The channels 10 are parallel. The channels 10 are closed spaces inside the vapor chamber 100. When the vapor chamber 100 is made of aluminum, the channels 10 in the vapor chamber 100 are formed by extrusion during the manufacturing process of the vapor chamber 100, and then the channels 10 thus formed are hermetically sealed by a sealing process. The working fluids 20 in the channels 10 are pure water.

Referring to FIG. 1, FIG. 2 and FIG. 3, in an embodiment, the channels 10 of the vapor chamber 100 each have an inner wall surface 11. The inner wall surface 11 has a closed outline to therefore define the channel 10. The inner wall surface 11 further has wick structures 111. The wick structures 111 are sintered powder, mesh, or convoluted (including grooved, columnar, coarse surfaces, regularly or irregularly convoluted). In this embodiment, the wick structures 111 are grooved wick structures.

Therefore, as soon as the vapor in the channels 10 reaches the condensation zone and condenses into liquid, the liquid returns to the evaporation zone by the capillary action of the wick structures 111 in the channels 10, thereby allowing the working fluids 20 to undergo evaporation and condensation alternately and thus enhance heat dissipation. In this embodiment, the vapor chamber 100 is made of aluminum and formed by an extrusion process characterized in that the channels 10, the wick structures 111 and the buffer zone 30 are simultaneously formed because of a special design of cross sections of a die used in the extrusion process. After the channels 10 have been filled with the working fluids 20, open edges of the vapor chamber 100, which are perpendicular to the extrusion direction, are sealed by sheet metal stamping, for example. Furthermore, the buffer zone 30 of the panel-shaped vapor chamber 100 is mechanically processed, for example, drilling a relief hole and bending by pressing.

In this embodiment, the vapor chamber 100 has a top side 12 and a bottom side 13 opposing the top side 12. The channels 10 extend in a direction which follows a straight line connecting the top side 12 and the bottom side 13. The wick structures 111 and the channels 10 of the vapor chamber 100 are formed simultaneously by extrusion; hence, the channels 10 and the wick structures 111 have the same extension direction and are produced in the same processing process.

Referring to FIG. 1 and FIG. 2, the buffer zone 30 can be mechanically processed, because it does not overlap the channels 10, or specifically speaking, it is disposed between two adjacent channels 10. Hence, the buffer zone 30 is substantially a solid panel structure before being mechanically processed. After being mechanically processed, the buffer zone 30 takes on different forms, for example, a non-solid panel structure or a non-solid structure.

Referring to FIG. 1 through FIG. 3, in an embodiment of the vapor chamber 100, the buffer zone 30 is a solid panel structure between two channels 10. In this embodiment, the channels 10 need not be present throughout the vapor chamber 100 but are provided and positioned according to positions of the heat sources 300 in the heat dissipation device 200.

Referring to FIG. 1 and FIG. 2, the vapor chamber 100 has a first buffer zone 30A. The first buffer zone 30A divides the channels 10 into a first heat dissipation portion H1 and a second heat dissipation portion H2. The first heat dissipation portion H1 and the second heat dissipation portion H2 each have the channels 10. In this embodiment, the first buffer zone 30A is of a width greater than each channel 10.

If the heat dissipation device 200 has two heat sources 300 corresponding in position to the first heat dissipation portion H1 and the second heat dissipation portion H2, the heat dissipation device 200 will require just one single vapor chamber 100 in order to dissipate heat from the two heat sources 300 and thus meet the need for heat dissipation. In case of a difference in temperature between the two heat sources 300, the adjacent first and second heat dissipation portions H1, H2 can be coordinated in dissipating heat—for example, heat is dissipated from the warmer first heat dissipation portion H1 through the cooler second heat dissipation portion H2.

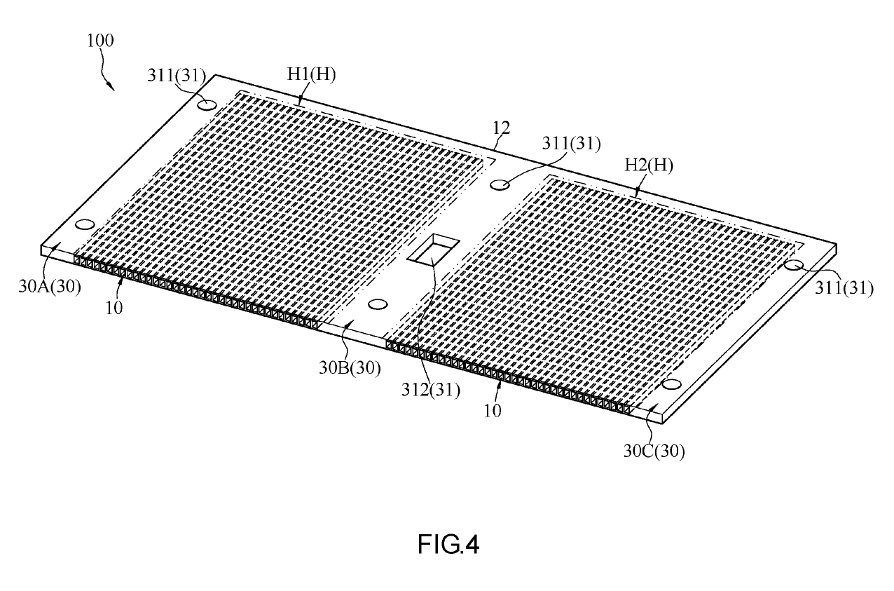

Referring to FIG. 4, in an embodiment, the vapor chamber 100 has a plurality of buffer zones 30. The buffer zones 30 include the first buffer zone 30A, a second buffer zone 30B and a third buffer zone 30C. The first buffer zone 30A, the second buffer zone 30B and the third buffer zone 30C divide the channels 10 into the first heat dissipation portion H1 and the second heat dissipation portion H2. The first heat dissipation portion H1 and the second heat dissipation portion H2 each have the channels 10. The first buffer zone 30A, the second buffer zone 30B and the third buffer zone 30C are substantially solid panel structures, whereas the first heat dissipation portion H1 and the second heat dissipation portion H2 are coplanar. The first heat dissipation portion H1 is defined between the first buffer zone 30A and the second buffer zone 30B, whereas the second heat dissipation portion H2 is defined between the second buffer zone 30B and the third buffer zone 30C.

The buffer zones 30 each have a plurality of apertures 31. The apertures 31 include first apertures 311 and second apertures 312. The first apertures 311 are round, whereas the second apertures 312 are square. The first buffer zone 30A and the third buffer zone 30C each have the first apertures 311, whereas the second buffer zone 30B has both the first apertures 311 and the second apertures 312.

Therefore, when the vapor chamber 100 is mounted on the heat dissipation device 200, the first heat dissipation portion H1 and the second heat dissipation portion H2 correspond in position to the heat sources 300. Any other electronic parts and components present in the vicinity of the heat sources 300 and protruding from the heat sources 300 at the same height as the heat sources 300 penetrate the first apertures 311 or the second apertures 312. Hence, the vapor chamber 100 can be as closest to the heat sources 300 as possible. Furthermore, the apertures 31 are applicable to different types of electronic parts and components and thus are shown in FIG. 4 illustratively rather than restrictively in terms of shape and position. The shapes of the apertures 31 are designed according to the shapes of the electronic parts and components to evade. The positions of the apertures 31 are designed according to the positions of the electronic parts and components to evade. Therefore, not only does the vapor chamber 100 dissipate heat simultaneously from the heat sources 300 located at different positions, but the vapor chamber 100 can also be as closest to the heat sources 300 as possible so as to be effective in dissipating heat even if electronic parts and components are present in the vicinity of the heat sources 300 and at a height greater than the heat sources 300.

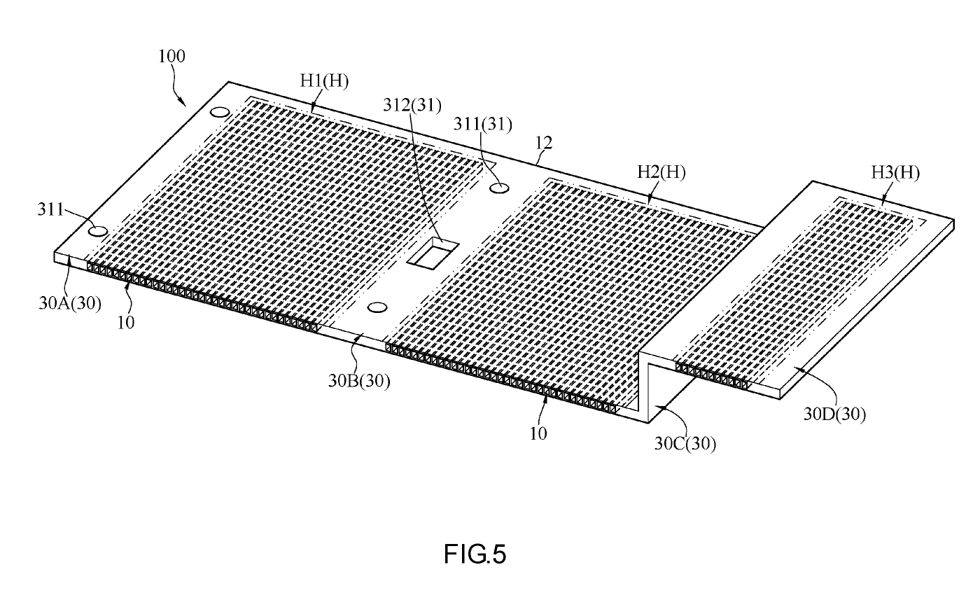

Referring to FIG. 5, in an embodiment, the buffer zones 30 are non-planar such that the vapor chamber 100 is applicable to the heat sources 300 located at positions which are not coplanar. In this embodiment, the buffer zones 30 include the first buffer zone 30A, the second buffer zone 30B, the third buffer zone 30C and a fourth buffer zone 30D. The first buffer zone 30A, the second buffer zone 30B, the third buffer zone 30C and the fourth buffer zone 30D divide the channels 10 into the first heat dissipation portion H1, the second heat dissipation portion H2 and a third heat dissipation portion H3. The first heat dissipation portion H1 and the second heat dissipation portion H2 are coplanar. The third heat dissipation portion H3 is not coplanar with the first heat dissipation portion H1 and the second heat dissipation portion H2.

In this embodiment, the first heat dissipation portion H1 is defined between the first buffer zone 30A and the second buffer zone 30B, the second heat dissipation portion H2 is defined between the second buffer zone 30B and the third buffer zone 30C, and the third heat dissipation portion H3 is defined between the third buffer zone 30C and the fourth buffer zone 30D.

The first buffer zone 30A, the second buffer zone 30B and the fourth buffer zone 30D are solid panel structures, whereas the third buffer zone 30C is a non-solid panel structure. The first buffer zone 30A has the first apertures 311. The second buffer zone 30B has the first apertures 311 and the second apertures 312. The third buffer zone 30C is a non-solid panel structure with two perpendicularly turning angles and two ends extending reversely.

Therefore, in this embodiment, to allow the vapor chamber 100 to correspond in position to the heat sources 300 located at positions which are not coplanar, the first heat dissipation portion H1 and the second heat dissipation portion H2 correspond in position to two coplanar heat sources 300, whereas the third heat dissipation portion H3 corresponds in position to the heat sources 300 located at positions which are not coplanar. Hence, the vapor chamber 100 corresponds in position to the heat sources 300 located at different positions, so as to achieve enhanced heat dissipation.

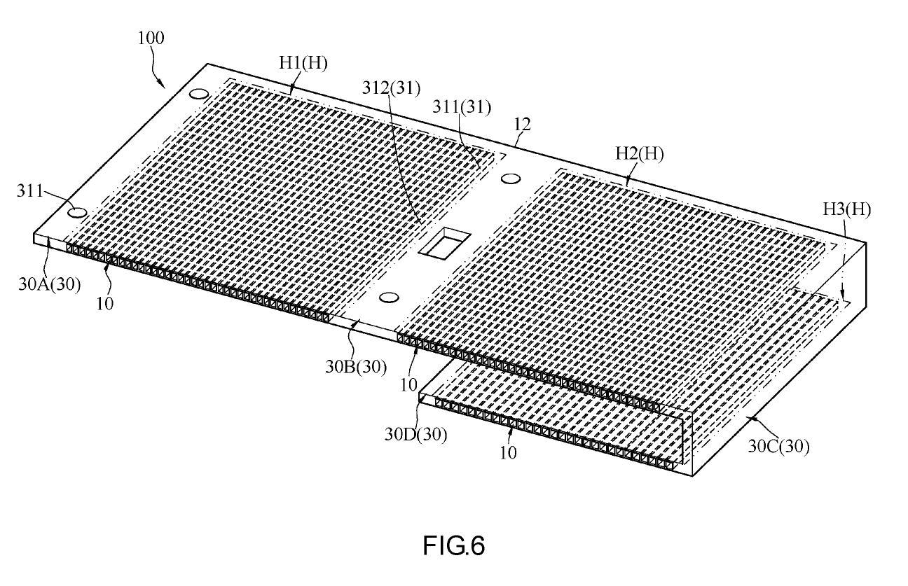

Referring to FIG. 6, in an embodiment, the buffer zones 30 include the first buffer zone 30A, the second buffer zone 30B, the third buffer zone 30C and the fourth buffer zone 30D. The first buffer zone 30A, the second buffer zone 30B, the third buffer zone 30C and the fourth buffer zone 30D divide the channels 10 into the first heat dissipation portion H1, the second heat dissipation portion H2 and the third heat dissipation portion H3. The first heat dissipation portion H1, the second heat dissipation portion H2 and the third heat dissipation portion H3 each have the channels 10. The first heat dissipation portion H1 and the second heat dissipation portion H2 are coplanar, whereas the third heat dissipation portion H3, the first heat dissipation portion H1, and the second heat dissipation portion H2 are not coplanar. The third heat dissipation portion H3 is parallel to the second heat dissipation portion H2.

In this embodiment, the first heat dissipation portion H1 is defined between the first buffer zone 30A and the second buffer zone 30B, the second heat dissipation portion H2 is defined between the second buffer zone 30B and the third buffer zone 30C, and the third heat dissipation portion H3 is defined between the third buffer zone 30C and the fourth buffer zone 30D.

The first buffer zone 30A, the second buffer zone 30B and the fourth buffer zone 30D are solid panel structures, whereas the third buffer zone 30C is a non-solid panel structure. The first buffer zone 30A has the first apertures 311. The second buffer zone 30B has the first apertures 311 and the second apertures 312. The third buffer zone 30C is a non-solid panel structure with two perpendicularly turning angles and two ends extending in the same direction. In this embodiment, the vapor chamber 100 corresponds in position to the heat sources 300 located at different positions to therefore achieve enhanced heat dissipation such that the vapor chamber 100 can simultaneously extend to two sides of a motherboard to increase the area of heat dissipation greatly.

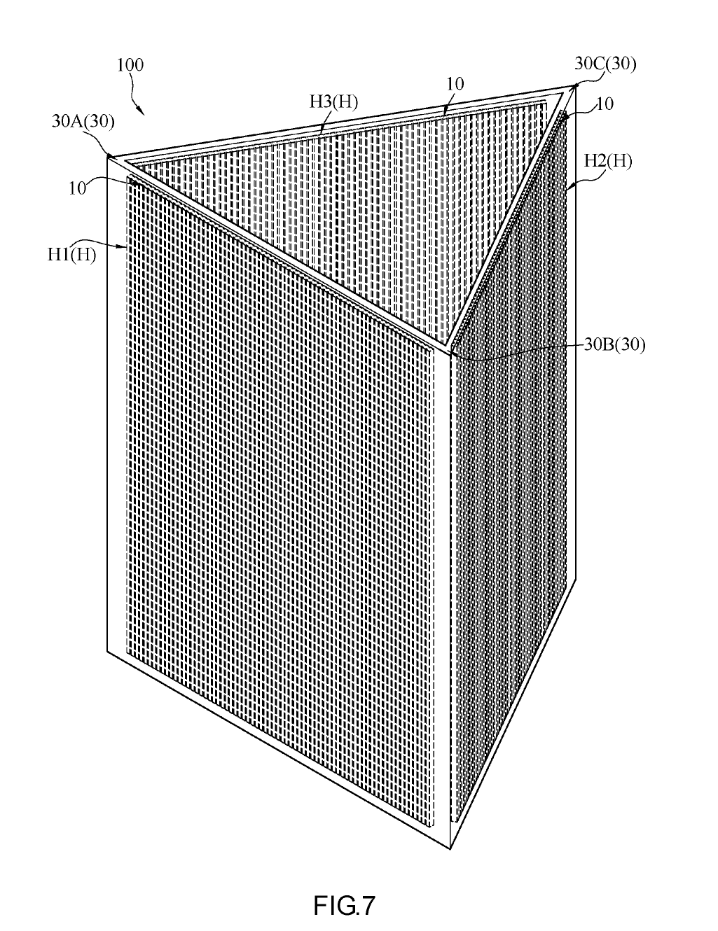

Referring to FIG. 7, in an embodiment, the buffer zones 30 include the first buffer zone 30A, the second buffer zone 30B and the third buffer zone 30C. The first buffer zone 30A, the second buffer zone 30B and the third buffer zone 30C divide the channels 10 into the first heat dissipation portion H1, the second heat dissipation portion H2 and the third heat dissipation portion H3. The first heat dissipation portion H1, the second heat dissipation portion H2 and the third heat dissipation portion H3 each have the channels 10. The first heat dissipation portion H1, the second heat dissipation portion H2 and the third heat dissipation portion H3 are not coplanar. The first heat dissipation portion H1, the second heat dissipation portion H2 and the third heat dissipation portion H3 are arranged in such a manner to form a hollow-core, triangular prism-shaped structure.

In this embodiment, the first heat dissipation portion H1, the second heat dissipation portion H2 and the third heat dissipation portion H3 are arranged in sequence. The first heat dissipation portion H1 is disposed between the first buffer zone 30A and the second buffer zone 30B. The second heat dissipation portion H2 is disposed between the second buffer zone 30B and the third buffer zone 30C. The third heat dissipation portion H3 is disposed between the third buffer zone 30C and the first buffer zone 30A.

The first buffer zone 30A, the second buffer zone 30B and the third buffer zone 30C are non-solid panel structures. The first buffer zone 30A, the second buffer zone 30B and the third buffer zone 30C are each a turning angle such that an included angle is formed between the first heat dissipation portion H1 and the second heat dissipation portion H2, between the second heat dissipation portion H2 and the third heat dissipation portion H3, and between the third heat dissipation portion H3 and the first heat dissipation portion H1. The included angles between the first heat dissipation portion H1 and the second heat dissipation portion H2, between the second heat dissipation portion H2 and the third heat dissipation portion H3, and between the third heat dissipation portion H3 and the first heat dissipation portion H1 are acute angles, but the present invention is not limited thereto.

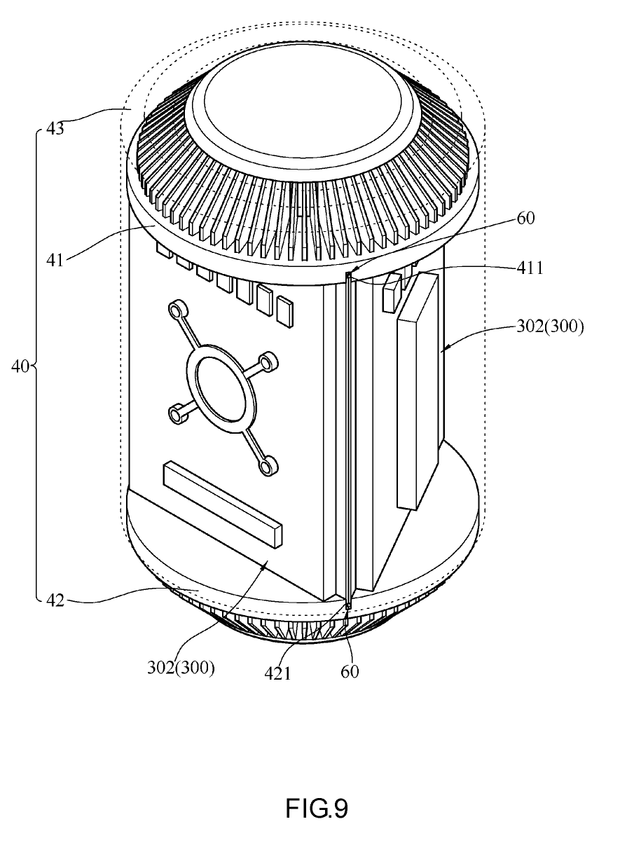

Referring to FIG. 8 through FIG. 10, in an embodiment, the heat dissipation device 200 comprises the vapor chamber 100, the heat sources 300 and a casing 400.

The vapor chamber 100 and the heat sources 300 are disposed in the casing 400. The heat sources 300 are disposed on the vapor chamber 100. Hence, the vapor chamber 100 dissipates heat from the heat sources 300 thoroughly.

In an embodiment, the casing 400 comprises an upper cover 41, a lower cover 42 and a body 43. The body 43 is a hollow-core cylinder. The upper cover 41 and the lower cover 42 are disposed at two ends of the body 43, respectively.

The vapor chamber 100 is disposed inside the body 43. The top side 12 of the vapor chamber 100 is positioned proximate to the upper cover 41. The bottom side 13 of the vapor chamber 100 is positioned proximate to the lower cover 42.

The heat sources 300 include a first heat source 301, a second heat source 302 and a third heat source 303. The first heat source 301 is a central processing unit (CPU). The second heat source 302 is a graphics processing unit (GPU). The third heat source 303 is a power module. The specific forms of the heat sources 300 are not restricted to the aforesaid embodiment, as the heat sources 300 may also be any other electronic devices. In this embodiment, the third heat source 303 is electrically connected to the first heat source 301 and the second heat source 302.

The first heat source 301 is disposed on the vapor chamber 100 and corresponds in position to the first heat dissipation portion H1. The second heat source 302 is disposed on the vapor chamber 100 and corresponds in position to the second heat dissipation portion H2. The third heat source 303 is disposed on the vapor chamber 100 and corresponds in position to the third heat dissipation portion H3. Areas which the channels 10 within the first heat dissipation portion H1, the second heat dissipation portion H2 and the third heat dissipation portion H3 are distributed across correspond in position to areas in which the first heat source 301, the second heat source 302 and the third heat source 303 are close to the vapor chamber 100, respectively. Hence, there is the largest possible contact area between each heat source 300 and a corresponding one of the heat dissipation portions H, thereby achieving optimal heat dissipation.

Therefore, when the first heat source 301, the second heat source 302 and the third heat source 303 operate and generate heat, the heat generated from the first heat source 301, the second heat source 302 and the third heat source 303 is directly transferred to the first heat dissipation portion H1, the second heat dissipation portion H2 and the third heat dissipation portion H3 such that the working fluids 20 within the first heat dissipation portion H1, the second heat dissipation portion H2 and the third heat dissipation portion H3 undergo evaporation and condensation alternately and quickly to speed up heat transfer.

In an embodiment, the vapor chamber 100 has an inward side 14 defined as one on which the first heat dissipation portion H1, the second heat dissipation portion H2 and the third heat dissipation portion H3 face each other, and an outward side 15 opposite the inward side 14. The heat sources 300 are disposed on the outward side 15 of the heat dissipation portions H of the vapor chamber 100, respectively.

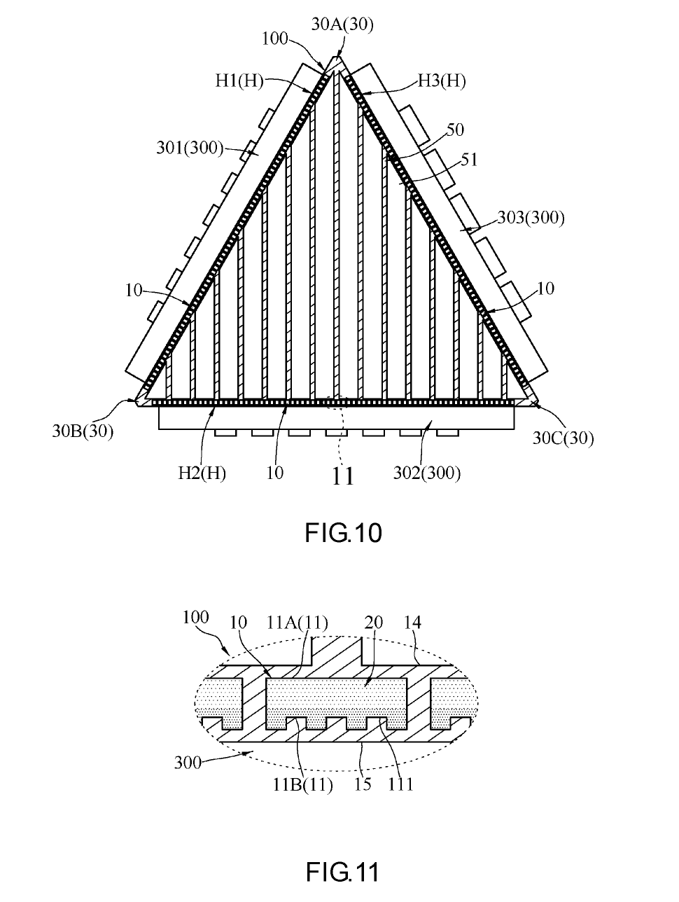

Referring to FIG. 10 and FIG. 11, the inner wall surface 11 of the channels 10 in the heat dissipation portions H has an inner-wall inward side 11A which is close to the inward side 14 and an inner-wall outward side 11B which is close to the outward side 15. In this embodiment, the wick structures 111 are disposed on the inner-wall outward side 11B of the channels 10 within the first heat dissipation portion H1, the second heat dissipation portion H2 and the third heat dissipation portion H3. With the wick structures 111 being positioned proximate to the heat sources 300, the working fluids 20 come into contact with heat quickly to speed up heat transfer. In this embodiment, the condensed working fluids 20 return to the bottom side 13 not only by the capillary action of the wick structures 111, but also by gravity, because the vapor chamber 100 and the casing 400 are upright. Therefore, it is feasible for the wick structures 111 to be disposed only on the inner-wall outward side 11B in order to increase the capacity of the channels 10 for receiving more working fluids 20. Moreover, the first heat source 301, the second heat source 302 and the third heat source 303 are positioned proximate to the bottom side 13 to not only heat up sufficiently the working fluids 20 returning to the bottom side 13 but also effectuate convection in the presence of rising hot air. Hence, an air feeding inlet is formed on the lower cover 42, and an air discharging outlet is formed on the upper cover 41.

In another embodiment, a plurality of auxiliary heat dissipating units 50 is disposed between the first heat dissipation portion H1, the second heat dissipation portion H2 and the third heat dissipation portion H3 of the vapor chamber 100 on the inward side 14. The auxiliary heat dissipating units 50 are each a sheet made of a metal or the vapor chamber 100 described in the aforesaid embodiments. The auxiliary heat dissipating units 50 are spaced apart to form a plurality of auxiliary heat dissipating channels 51. The auxiliary heat dissipating channels 51 are in communication in the direction of a straight line connecting the top side 12 and the bottom side 13 of the vapor chamber 100. In this embodiment, the vapor chamber 100 is made of aluminum and formed by an extrusion process characterized in that the channels 10, the wick structures 111, the buffer zones 30 and the auxiliary heat dissipating units 50 are simultaneously formed because of a special design of cross sections of a die used in the extrusion process. Parallel heat-dissipating fins are formed from the auxiliary heat dissipating units 50.

Therefore, when the heat sources 300 of the heat dissipation device 200 operate and generate heat, the heat comes into direct contact with the vapor chamber 100 such that hot air accumulates between the first heat dissipation portion H1, the second heat dissipation portion H2 and the third heat dissipation portion H3 of the vapor chamber 100 on the inward side 14. In this embodiment, the auxiliary heat dissipating channels 51 between the first heat dissipation portion H1, the second heat dissipation portion H2 and the third heat dissipation portion H3 on the inward side 14 are conducive to an increase in the contact area between the hot air and the auxiliary heat dissipating units 50 such that the hot air is cooled down quickly.

In this embodiment, the wick structures 111 are disposed on both the inner-wall inward side 11A and the inner-wall outward side 11B of the channels 10 within the first heat dissipation portion H1, the second heat dissipation portion H2 and the third heat dissipation portion H3 such that the working fluids 20 in the vapor chamber 100 have access to more contact area for the sake of condensation, come into contact with heat sufficiently, and effectuate heat transfer quickly.

In an embodiment, a fan is disposed in the upper cover 41 of the casing 400. The fan operates in conjunction with the aforesaid convection such that air inside the casing 400 is drawn from the lower cover 42 and delivered to the upper cover 41 to force the air through the auxiliary heat dissipating channels 51 and thereby enhance the efficiency of heat dissipation.

In an embodiment, the vapor chamber 100 further has a plurality of coupling portions 60. The coupling portions 60 are disposed on the top side 12 and the bottom side 13 of the vapor chamber 100. Mounting notches 411, 421 are disposed on outer peripheral surfaces of the upper cover 41 and the lower cover 42, respectively. The coupling portions 60 of the vapor chamber 100 correspond in position to and are received in the mounting notches 411, 421 of the upper cover 41 and the lower cover 42. The coupling portions 60 are fixed to the mounting notches 411, 421 by fasteners, such as screws, bolts, or rivets, such that the vapor chamber 100 and the casing 400 are coupled together.

Although the present invention is disclosed above by preferred embodiments, the preferred embodiments are not restrictive of the present invention. Changes and modifications can be made by persons skilled in the art to the preferred embodiments without departing from the spirit and scope of the present invention. Accordingly, the legal protection for the present invention shall be defined by the appended claims.

What is claimed is:

1. A vapor chamber, comprising:
a plurality of channels;
a plurality of working fluids undergoing evaporation and condensation alternately in the channels, respectively; and
a first buffer zone defined between every two adjacent ones of the channels to enable mechanical processing and adapted to divide the channels into a first heat dissipation portion and a second heat dissipation portion.

2. The vapor chamber of claim 1, wherein the first buffer zone is substantially solid before undergoing the mechanical processing.

3. The vapor chamber of claim 1, wherein the vapor chamber has a top side and a bottom side opposing the top side, with the channels each extending from the bottom side to the top side and each having an inner wall surface, the inner wall surface further has a plurality of wick structures.

4. The vapor chamber of claim 1, wherein the first buffer zone forms a curved surface or a turning angle to allow the vapor chamber to extend in different directions.

5. The vapor chamber of claim 1, wherein the first heat dissipation portion and the second heat dissipation portion are coplanar.

6. The vapor chamber of claim 1, wherein the first heat dissipation portion and the second heat dissipation portion are not coplanar.

7. A heat dissipation device adapted to dissipate heat generated from a heat source, the heat dissipation device comprising:
a casing; and
a vapor chamber received in the casing, the vapor chamber having a top side and a bottom side opposing the top side, with the heat source disposed at the vapor chamber, the vapor chamber comprising:
a plurality of channels each extending from the bottom side to the top side;
a plurality of working fluids undergoing evaporation and condensation alternately in the channels, respectively; and
a first buffer zone defined between every two adjacent ones of the channels to enable mechanical processing and adapted to divide the channels into a first heat dissipation portion and a second heat dissipation portion.

8. The heat dissipation device of claim 7, wherein an included angle is formed between the first heat dissipation portion and the second heat dissipation portion by the first buffer zone.

9. The heat dissipation device of claim 7, wherein the vapor chamber comprises a second buffer zone, with the second heat dissipation portion disposed between the first buffer zone and the second buffer zone, such that the first buffer zone and the second buffer zone divide the channels into the first heat dissipation portion, the second heat dissipation portion and a third heat dissipation portion.

10. The heat dissipation device of claim 7, wherein the vapor chamber has a triangular cross section perpendicular to the top side.
